(19) United States
(12) Patent Application Publication
(10) Pub. No.: US 2026/0321945 A1
(43) Pub. Date: Oct. 15, 2026

(54) MULTILAYER FILTER AND FRONT END MODULE COMPRISING SAME

(71) Applicant: LG INNOTEK CO., LTD., Seoul (KR)

(72) Inventors: Jong Min KIM, Seoul (KR); Yu Seon KIM, Seoul (KR); Choul Hee HONG, Seoul (KR)

(73) Assignee: LG INNOTEK CO., LTD., Seoul (KR)

(21) Appl. No.: 19/483,779

(22) PCT Filed: May 22, 2024
(86) PCT No.: PCT/KR2024/095838

§ 371 Date: Nov. 12, 2025

(30) Foreign Application Priority Data
May 23, 2023 (KR) 10-2023-0066316

(51) Int. Cl. H01P 1/201; H03H 9/64

(52) U.S. Cl. CPC H01P 1/201; H03H 9/64

(57) ABSTRACT

A multilayer filter of an embodiment comprises: first and second ground layers; a plurality of conductive pattern layers disposed between the first ground layer and the second ground layer; and a dielectric layer disposed between the first and second ground layers and the plurality of conductive pattern layers, wherein adjacent conductive pattern layers among the plurality of conductive pattern layers include capacitance pattern layers forming a first capacitance, and at least some of the plurality of conductive pattern layers include an inductance pattern layer forming an inductor, wherein the capacitance pattern layers face each of the first and second ground layers to form parasitic capacitance, and filter a signal having a desired frequency band by using the first capacitance, the inductor, and the parasitic capacitance.

### CROSS REFERENCE TO RELATED APPLICATIONS

This application is the National Phase of PCT International Application No. PCT/KR2024/095838, filed on May 22, 2024, which claims priority under 35 U.S.C. 119(a) to Patent Application No. 10-2023-0066316, filed in the Republic of Korea on May 23, 2023, all of which are hereby expressly incorporated by reference into the present application.

### TECHNICAL FIELD

Embodiments relate to a multilayer filter and a front end module including the same.

### BACKGROUND ART

Wi-Fi 6E is a next-generation extension of Wi-Fi 6 (also referred to as 802.11ax) that enables operation in the 6 GHz band in addition to the currently supported 2.4 GHz and 5 GHz bands. Wi-Fi 6E operates under the same Wi-Fi standard as Wi-Fi 6, but with an expanded spectrum. The 6 GHz band is a new frequency band in a range from 5.945 GHz to 7.125 GHz, allowing an additional spectrum of up to 1,200 MHz. Unlike the existing frequency bands in which many channels are crowded in a limited spectrum, the 6 GHz band avoids overlap and interference issues, and enables use of networks with greater bandwidth, higher speed, and lower latency.

However, as the frequency increases, the directivity of the radio wave increases, resulting in greater attenuation of the level of a propagated signal, which leads to decrease in data throughput. In order to compensate for this, a front end module is required to distinguish frequency bands.

A front end module (FEM) is a transceiver that controls radio signals used in a mobile communication terminal, and refers to a composite component which various electronic parts are sequentially implemented on a single substrate so that the integration space is minimized. Most conventional front end modules employ an acoustic wave filter such as a surface acoustic wave (SAW) filter or a bulk acoustic wave (BAW) filter. Accordingly, the cost and size of the conventional front end modules increase, and therefore, research on this issue is underway.

### DISCLOSURE

### Technical Problem

Embodiments provide a low-cost and compact multilayer filter and a front end module including the same.

### Technical Solution

A multilayer filter according to an embodiment may include first and second ground plurality of conductive pattern layers disposed between the first ground layer and the second ground layer, and a dielectric layer disposed between the first and second ground layers and the plurality of conductive pattern layers. Among the plurality of conductive pattern layers, adjacent conductive pattern layers may include capacitance pattern layers forming a first capacitance, and at least some of the plurality of conductive pattern layers may include inductance pattern layers forming an inductor. The capacitance pattern layers may face the first and second ground layers to form a parasitic capacitance, and may filter a signal having a desired frequency band using the first capacitance, the inductor, and the parasitic capacitance.

In an example, the capacitance pattern layers and the inductance pattern layers may have a symmetrical shape with respect to an imaginary horizontal line passing through the center of a long axis of the multilayer filter and parallel to a short-axis direction of the multilayer filter.

In an example, the plurality of conductive pattern layers may include first to third conductive pattern layers sequentially stacked between the first ground layer and the second ground layer.

In an example, the inductance pattern layers may include a first inductor layer disposed on the second conductive pattern layer, a second inductor layer disposed across the second conductive pattern layer and the third conductive pattern layer, a third inductor layer disposed on the first conductive pattern layer, and a fourth inductor layer disposed on the third conductive pattern layer.

In an example, each of the first, second, third, and fourth inductor layers may have a planar shape bent at least once in a horizontal direction.

In an example, the capacitance pattern layers may include a first capacitor layer disposed on the second conductive pattern layer and a second capacitor layer disposed on the third conductive pattern layer and facing the first capacitor layer to form the first capacitance.

In an example, the plurality of conductive pattern layers may further include fourth and fifth conductive pattern layers sequentially stacked between the third conductive pattern layer and the second ground layer.

In an example, the capacitance pattern layers may further include a third capacitor layer connected to the first capacitor layer and a fourth capacitor layer connected to the second capacitor layer.

In an example, the multilayer filter may include a first via connecting the first capacitor layer to the third capacitor layer and a second via connecting the second capacitor layer to the fourth capacitor layer.

In an example, the first capacitance may include an 11^{th} capacitance formed by the first capacitor layer and the second capacitor layer facing each other, a 12^{th} capacitance formed by the second capacitor layer and the third capacitor layer facing each other, and a 13^{th} capacitance formed by the third capacitor layer and the fourth capacitor layer facing each other.

In an example, the parasitic capacitance may include a first parasitic capacitance formed by the first and third capacitor layers and the first and second ground layers facing each other and a second parasitic capacitance formed by the second and fourth capacitor layers and the first and second ground layers facing each other.

In an example, the first capacitor layer may include 11^{th} and 12^{th} capacitor layers facing each other while being spaced apart from each other by a first distance in a horizontal direction, and the third capacitor layer may include 31^{st} and 32^{nd} capacitor layers facing each other while being spaced apart from each other by a second distance in the horizontal direction.

In an example, the first or second distance may be 50 μm to 300 μm.

In an example, the first via may include an 11^{th} via connecting the 11^{th} capacitor layer to the 31^{st} capacitor layer and a 12^{th} via connecting the 12^{th} capacitor layer to the 32^{nd} capacitor layer.

In an example, the second capacitor layer may include a first through-hole formed to allow the 11^{th} via to pass therethrough and spaced apart from the 11^{th} via and a second through-hole formed to allow the 12^{th} via to pass therethrough and spaced apart from the 12^{th} via.

In an example, the 31^{st} and 32^{nd} capacitor pattern layers may have a planar shape and may be disposed to be spaced apart from each other with the second via interposed therebetween.

In an example, the second inductor layer may include a second upper inductor layer having one end connected to the first capacitor layer and disposed on the second conductive pattern layer and a second lower inductor layer having one end connected to the other end of the second upper inductor layer and the other end connected to the second capacitor layer and disposed on the third conductive pattern layer.

In an example, the multilayer filter may include a 31^{st} via connected to the 11^{th} capacitor layer, to one end of a 21^{st} upper inductor layer, which is a part of the second upper inductor layer, and to one end of an 11^{th} inductor layer, which is a part of the first inductor layer, a 32^{nd} via connected to the 12^{th} capacitor layer, to one end of a 22^{nd} upper inductor layer, which is another part of the second upper inductor layer, and to one end a 12^{th} inductor layer, which is another part of the first inductor layer, a 41^{st} via connected to the other end of the 11^{th} inductor layer and to a first port, a 42^{nd} via connected to the other end of the 12^{th} inductor layer and to a second port, a fifth via connecting one end of a 31^{st} inductor layer, which is a part of the third inductor layer, to the first ground layer, a 61^{st} via connected to the other end of the 21^{st} upper inductor layer, a 62^{nd} via connected to the other end of the 22^{nd} upper inductor layer, a 71^{st} via connected to one end of a 41^{st} inductor layer, which is a part of the fourth inductor layer, a 72^{nd} via connected to one end of a 42^{nd} inductor layer, which is another part of the fourth inductor layer, and at least one eighth via connecting the first ground layer to the second ground layer.

In an example, the other end of the 31^{st} inductor layer may be connected to the 11^{th} via, one end and the other end of a 32^{nd} inductor layer, which is another part of the third inductor layer, may be connected to the 5^{th} via and the 12^{th} via, respectively, a 21^{st} lower inductor layer, which is a part of the second lower inductor layer, may have one end and the other end connected to the 61^{st} via and the second capacitor layer, respectively, a 22^{nd} lower inductor layer, which is another part of the second lower inductor layer, may have one end and the other end connected to the 62^{nd} via and the second capacitor layer, respectively, and the other end of each of the 41^{st} inductor layer and the 42^{nd} inductor layer may be connected to the second capacitor layer.

A multilayer filter according to another embodiment may include an 11^{th} inductor having one end connected to a first port, a 12^{th} inductor having one end connected to a second port, a 21^{st} inductor having one end connected to the other end of the 11^{th} inductor, a 22^{nd} inductor having one end connected to the other end of the 12^{th} inductor, a 31^{st} inductor connected between the other end of the 11^{th} inductor and ground, a 32^{nd} inductor connected between the other end of the 12^{th} inductor and the ground, a 41^{st} inductor connected between the other end of the 21^{st} inductor and the ground, a 42^{nd} inductor connected between the other end of the 22^{nd} inductor and the ground, an 11^{th} capacitor connected in parallel to the 21^{st} inductor, a 12^{th} capacitor connected in parallel to the 22^{nd} inductor, a 21^{st} capacitor connected in parallel to the 31^{st} inductor, a 22^{nd} capacitor connected in parallel to the 32^{nd} inductor, and a third capacitor connected in parallel to the 41^{st} and 42^{nd} inductors between a junction of the 21^{st} inductor and the 22^{nd} inductor and the ground.

In an example, the 21^{st}, 22^{nd}, and third capacitors may be parasitic capacitances.

A front end module according to a further embodiment may include an antenna, a first amplifier configured to amplify a signal received through the antenna, a multilayer filter configured to filter the signal amplified by the first amplifier and to output the filtered signal, a second amplifier configured to amplify a signal to be transmitted through the antenna, and a switch disposed between the antenna and each of an input of the first amplifier and an output of the second amplifier.

### Advantageous Effects

The multilayer filter and the front end module including the same according to the embodiments have a small size, allow easy frequency tuning, and have a configuration capable of easily increasing capacitance and inductance.

### DESCRIPTION OF DRAWINGS

FIG. 1 is a cross-sectional view of a multilayer filter according to an embodiment.

FIG. 2 is a perspective view schematically showing an embodiment of the multilayer filter shown in FIG. 1.

FIG. 3 is a circuit diagram of a multilayer filter according to an embodiment.

FIG. 4 is a perspective view showing the appearance of a multilayer filter according to an embodiment.

FIG. 5A is a perspective view of the multilayer filter shown in FIG. 4 with a first ground layer removed.

FIG. 5B is a plan view of the perspective view shown in FIG. 5A.

FIG. 6 is a plan view of the first conductive pattern layer shown in FIG. 5B.

FIG. 7A is a perspective view of FIG. 5A with the first conductive pattern layer removed.

FIG. 7B is a plan view of a second conductive pattern layer.

FIG. 8A is a perspective view of FIG. 7A with the second conductive pattern layer removed.

FIG. 8B is a plan view of a third conductive pattern layer.

FIG. 9A is a perspective view of FIG. 8A with the third conductive pattern layer removed.

FIG. 9B is a plan view of a fourth conductive pattern layer.

FIG. 10A is a perspective view of FIG. 9A with the fourth conductive pattern layer removed.

FIG. 10B is a plan view of a fifth conductive pattern layer.

FIG. 11 is a cross-sectional view of the multilayer filter shown in FIG. 4, taken along line I-I′.

FIG. 12 is a graph showing a result of examining the performance of the multilayer filter according to the embodiment.

FIG. 13 is a block diagram of a front end module according to an embodiment.

### BEST MODEL

Hereinafter, exemplary embodiments of the present disclosure will be described in detail with reference to the accompanying drawings.

The technical spirit of the disclosure is not limited to the embodiments to be described, and may be implemented in various other forms, and one or more of the components may be selectively combined and substituted for use without exceeding the scope of the technical spirit of the disclosure.

In addition, terms (including technical and scientific terms) used in the embodiments of the disclosure, unless specifically defined and described explicitly, are to be interpreted as having meanings that may be generally understood by those having ordinary skill in the art to which the disclosure pertains, and meanings of terms that are commonly used, such as terms defined in a dictionary, should be interpreted in consideration of the context of the relevant technology.

Further, the terms used in the embodiments of the disclosure are for explaining the embodiments and are not intended to limit the disclosure. In this specification, the singular forms may also include plural forms unless otherwise specifically stated in a phrase, and in the case in which “at least one (or one or more) of A, B, or C” is stated, it may include one or more of all possible combinations of A, B, and C.

In addition, in describing the components of the embodiments of the disclosure, terms such as “first,” “second,” “A,” “B,” “ (a), ” and “(b)” can be used. Such terms are only for distinguishing one component from another component, and do not determine the nature, sequence, or procedure of the corresponding constituent elements.

In addition, when it is described that a component is “connected,” “coupled” or “joined” to another component, the description may include not only being directly “connected,” “coupled” or “joined” to the other component but also being “connected,” “coupled” or “joined” by another component between the component and the other component.

In addition, in the case of being described as being formed or disposed “above (on)” or “below (under)” another component, the description includes not only the case where the two components are in direct contact with each other, but also the case where one or more other components are formed or disposed between the two components. In addition, when expressed as “above (on)” or “below (under), ” it may refer to a downward direction as well as an upward direction with respect to one element.

Hereinafter, a multilayer filter 100 or 100A and a front end module 200 including the same according to embodiments will be described with reference to the accompanying drawings. The multilayer filter 100 or 100A will be described using the Cartesian coordinate system (x-axis, y-axis, z-axis) for convenience of description, but may also be described using other coordinate systems. In the Cartesian coordinate system, the x-axis, the y-axis, and the z-axis are perpendicular to each other, but the embodiments are not limited thereto. That is, the x-axis, the y-axis, and the z-axis may intersect each other obliquely. Hereinafter, for convenience of description, the x-axis direction will be referred to as a “first direction,” the y-axis direction will be referred to as a “second direction,” and the z-axis direction will be referred to as a “third direction.”

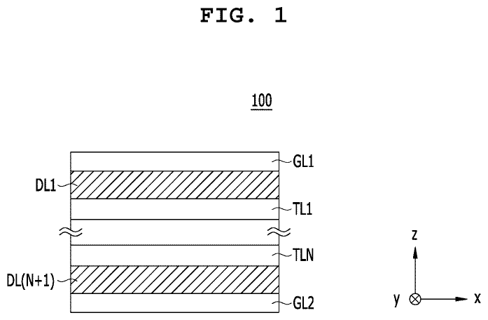

FIG. 1 is a cross-sectional view of a multilayer filter 100 according to an embodiment.

According to the embodiment, the multilayer filter 100 includes multiple layers. That is, as shown in FIG. 1, the multilayer filter 100 may include a first ground layer GL1, a second ground layer GL2, first to N^{th} conductive pattern layers TL1 to TLN, and dielectric layers (or printed circuit boards (PCBs) ) DL1 to DL (N+1). In this case, N is a positive integer of 3 or greater.

The first to Nth conductive pattern layers TL1 to TLN may be sequentially stacked in the third direction between the first ground layer GL1 and the second ground layer GL2.

According to the embodiment, a ground connected to each of the first and second ground layers GL1 and GL2 may be an RF ground or a DC ground. In this case, when the multilayer filter 100 is a standalone component, each of the first and second ground layers GL1 and GL2 may be connected to an RF ground, and when the multilayer filter 100 is included in a front end module 200 to be described later, each of the first and second ground layers GL1 and GL2 may be connected to an RF or DC ground. However, the embodiments are not limited thereto.

In addition, the dielectric layers DL1 to DL (N+1) may be disposed between the first and second ground layers GL1 and GL2 and the first to N^{th} conductive pattern layers TL1 to TLN. In detail, the first dielectric layer DL1 may be disposed between the first ground layer GL1 and the first conductive pattern layer TL1, and the (N+1)^{th} dielectric layer DL (N+1) may be disposed between the N^{th} conductive pattern layer TLN and the second ground layer GL2. Similarly, the k^{th} dielectric layer DLk may be disposed between the k^{th} conductive pattern layer TLk and the (k+1)^{th} conductive pattern layer TL (k+1). In this case, 1≤k≤N−1. In this manner, the number of dielectric layers may be greater than the number of conductive pattern layers by one.

For example, when N=3, the first to third conductive pattern layers TL1 to TL3 may be sequentially stacked between the first ground layer GL1 and the second ground layer GL2, and the first to fourth dielectric layers DL1 to DL4 may be disposed between the first ground layer GL1, the first to third conductive pattern layers TL1 to TL3, and the second ground layer GL2.

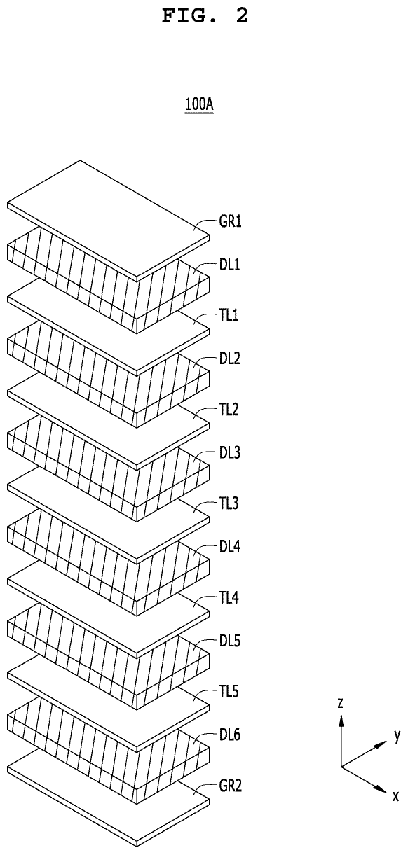

FIG. 2 is a perspective view schematically showing an embodiment 100A of the multilayer filter 100 shown in FIG. 1.

When N=5, as shown in FIG. 2, the first to fifth conductive pattern layers TL1 to TL5 may be sequentially stacked between the first ground layer GL1 and the second ground layer GL2, and the first to sixth dielectric layers DL1 to DL6 may be disposed between the first ground layer GL1, the first to fifth conductive pattern layers TL1 to TL5, and the second ground layer GL2.

Among the first to Nth conductive pattern layers TL1 to TLN, adjacent conductive pattern layers may include capacitance pattern layers forming a first capacitance. For example, the second conductive pattern layer TL2 and the third conductive pattern layer TL3, which are vertically adjacent to each other, may each include a capacitor pattern layer implemented as a conductor having electrical conductivity, and the third dielectric layer DL3 formed of a dielectric material may be disposed therebetween so that the first capacitance is formed.

In addition, at least some of the first to N^{th} conductive pattern layers TL1 to TLN may include inductance pattern layers forming an inductor. To this end, the inductance pattern layers may be implemented as a conductor. For example, each of the first to third conductive pattern layers TL1 to TL3 may include an inductance pattern layer.

In addition, according to the embodiment, the capacitance pattern layers forming the first capacitor may face the first and second ground layers GL1 and GL2, thereby forming parasitic capacitances that form a second capacitor and a third capacitor.

The multilayer filter 100 or 100A according to the embodiment implemented as described above may be a band-pass filter that filters a signal having a desired frequency band using the first capacitor, the inductor, and the second and third capacitors.

Hereinafter, a filter according to an embodiment, in which N=5, the second to fifth conductive pattern layers TL2 to TL5, except for the first conductive pattern layer TL1, include capacitance pattern layers, and the first, second, and third conductive pattern layers TL1 to TL3 include inductance pattern layers, will be described.

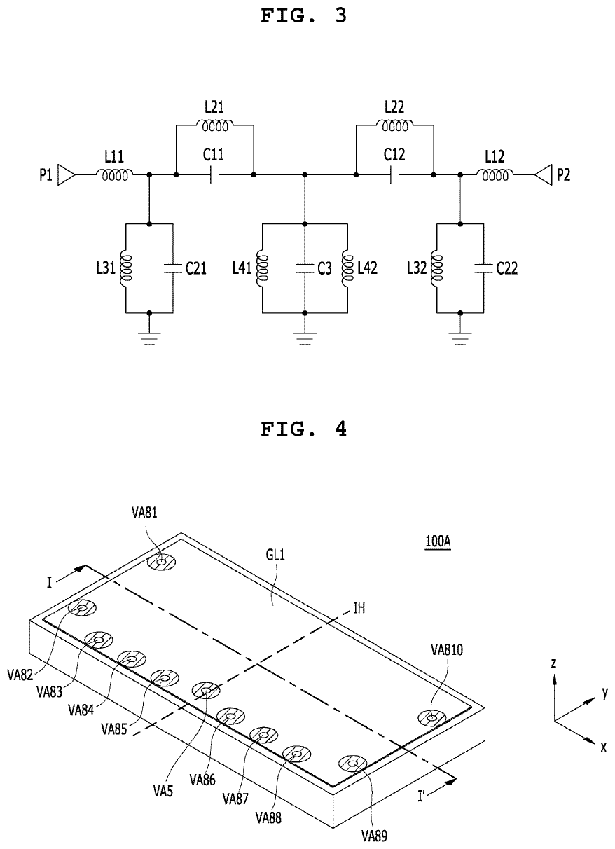

FIG. 3 is a circuit diagram of a multilayer filter according to an embodiment.

The multilayer filter according to the embodiment shown in FIG. 3 is a type of band-pass filter, and includes 11^{th}, 12^{th}, 21^{st}, 22^{nd}, 31^{st}, 32^{nd}, 41^{st}, and 42^{nd} inductors L11, L12, L21, L22, L31, L32, L41, and L42, and 11^{th}, 12^{th}, 21^{st}, 22^{nd}, and 3^{rd} capacitors C11, C12, C21, C22, and C3.

The 11^{th} inductor L11 has one end connected to a first port P1. The 12^{th} inductor L12 has one end connected to a second port P2.

The first port P1 is an input port into which a signal is introduced, and the second port P2 may be an output port from which a signal is output. Alternatively, the first port P1 may be an output port from which a signal is output, and the second port P2 may be an input port into which a signal is introduced.

The 21^{st} inductor L21 has one end connected to the other end of the 11^{th} inductor L11, and the 22^{nd} inductor L22 has one end connected to the other end of the 12^{th} inductor L12. The 31^{st} inductor L21 may be connected between the other end of the 11^{th} inductor L11, that is, a junction between the 11^{th} inductor L11 and the 21^{st} inductor L21, and ground, and the 32^{nd} inductor L32 may be connected between the other end of the 12^{th} inductor L12, that is, a junction between the 12^{th} inductor L12 and the 22^{nd} inductor L22, and ground.

The 41^{st} inductor L41 may be connected between the other end of the 21^{st} inductor L21, that is, a junction between the 21^{st} inductor L21 and the 22^{nd} inductor L22, and ground, and the 42^{nd} inductor L42 may be connected between the other end of the 22^{nd} inductor L22, that is, a junction between the 21^{st} inductor L21 and the 22^{nd} inductor L22, and ground.

Meanwhile, the 11^{th} capacitor C11 may be connected in parallel to the 21^{st} inductor L21, and the 12^{th} capacitor C12 may be connected in parallel to the 22^{nd} inductor L22.

The 21^{st} capacitor C21 is connected in parallel to the 31^{st} inductor L31, and the 22^{nd} capacitor C22 is connected in parallel to the 32^{nd} inductor L32.

The 3^{rd} capacitor C3 is connected in parallel to the 41^{st} and 42^{nd} inductors L41 and L42 between a junction of the 21^{st} and 22^{nd} inductors L21 and L22 and ground.

According to the embodiment, the 21^{st}, 22^{nd}, and 3^{rd} capacitors C21, C22, and C3 may be implemented as parasitic capacitances.

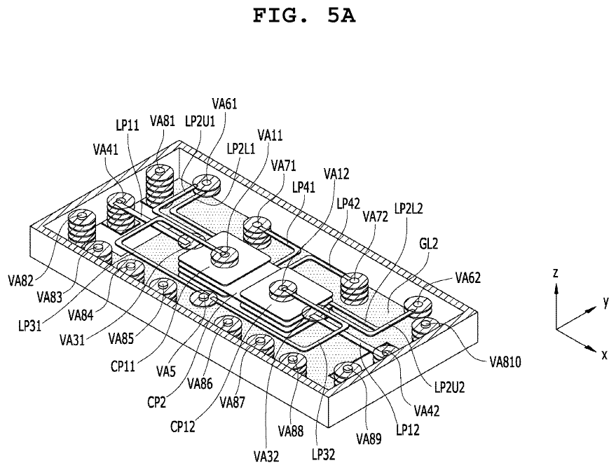

The multilayer filter according to the embodiment may have various configurations to perform the function of the band-pass filter shown in FIG. 3. An example will be described below with reference to FIGS. 4 to 10B, but the embodiments are not limited thereto. That is, the multilayer filter according to the embodiment may implement a filter having a circuit configuration different from that shown in FIG. 3.

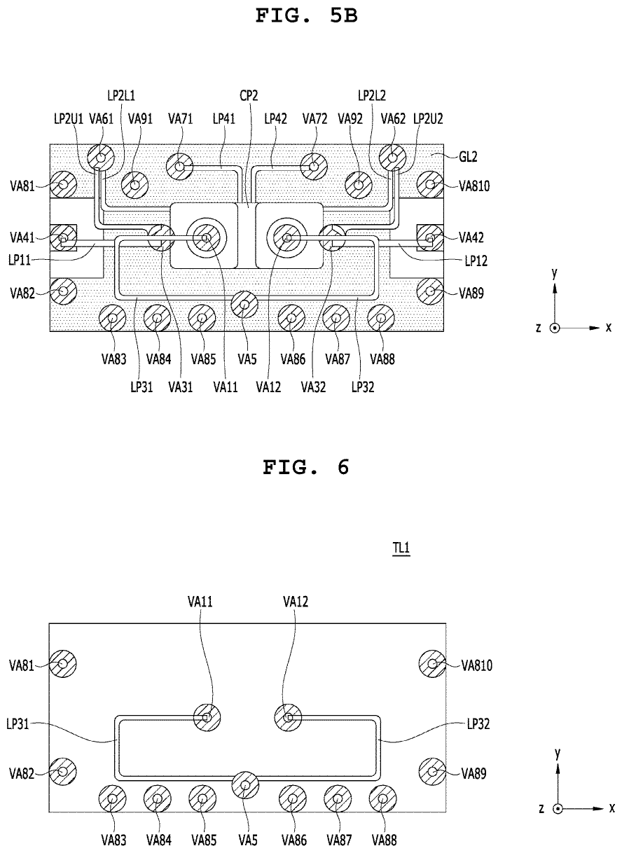

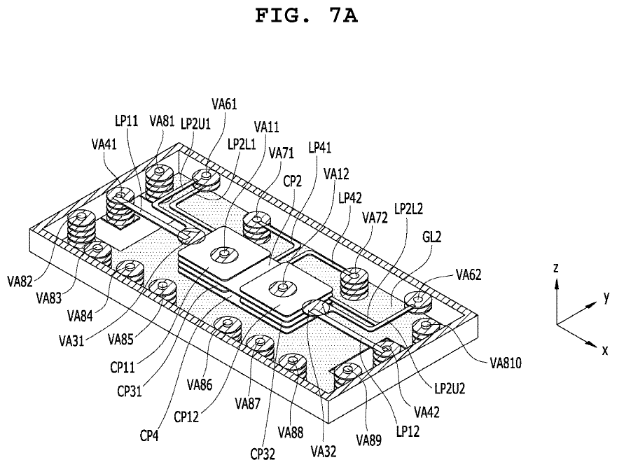

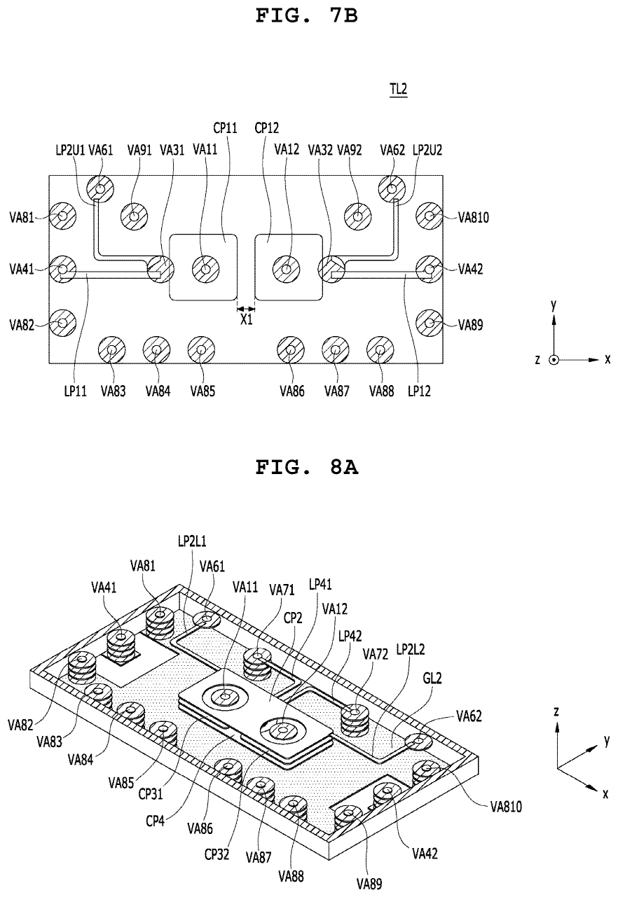

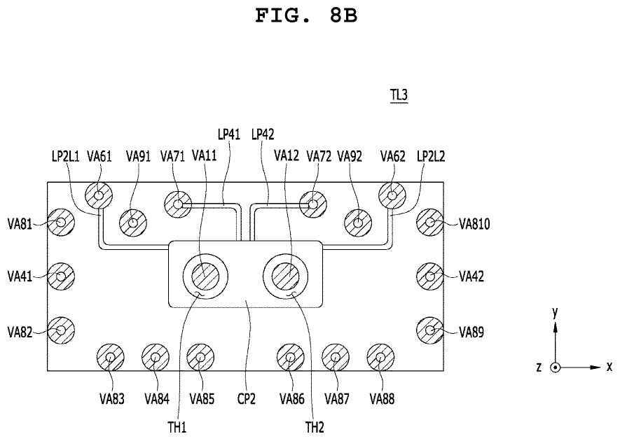

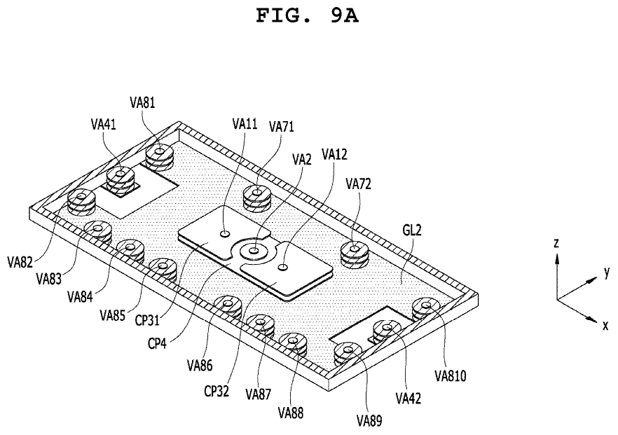

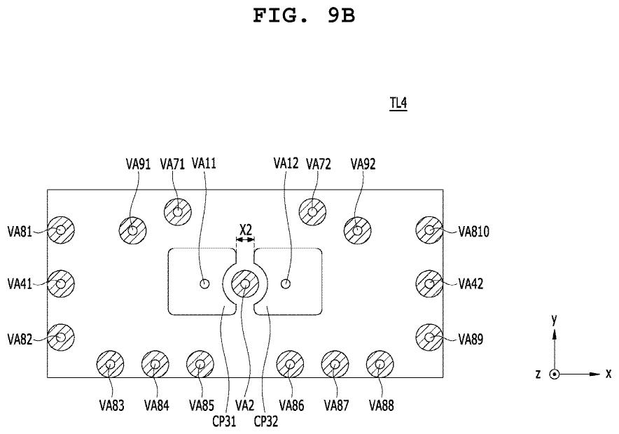

FIG. 4 is a perspective view showing the appearance of a multilayer filter according to an embodiment. FIG. 5A is a perspective view of the multilayer filter shown in FIG. 4 with the first ground layer GL1 removed. FIG. 5B is a plan view of the perspective view shown in FIG. 5A. FIG. 6 is a plan view of the first conductive pattern layer TL1 shown in FIG. 5B. FIG. 7A is a perspective view of FIG. 5A with the first conductive pattern layer TL1 removed. FIG. 7B is a plan view of the second conductive pattern layer TL2. FIG. 8A is a perspective view of FIG. 7A with the second conductive pattern layer TL2 removed. FIG. 8B is a plan view of the third conductive pattern layer TL3. FIG. 9A is a perspective view of FIG. 8A with the third conductive pattern layer TL3 removed. FIG. 9B is a plan view of the fourth conductive pattern layer TL4. FIG. 10A is a perspective view of FIG. 9A with the fourth conductive pattern layer TL4 removed. FIG. 10B is a plan view of the fifth conductive pattern layer TL5.

As in the case in which the circuit shown in FIG. 3 is bilaterally symmetrical, the capacitance pattern layers and the inductance pattern layers shown in FIGS. 4 to 10B may have a symmetrical shape with respect to an imaginary horizontal line IH that passes through the center of the long axis (i.e., the x-axis) of the multilayer filter and is parallel to the second direction, which is the short-axis direction of the multilayer filter.

The inductance pattern layers may include first inductor layers LP11 and LP12, second inductor layers LP2U1, LP2U2, LP2L1, LP2L2, third inductor layers LP31 and LP32, and fourth inductor layers LP41 and LP42.

The first inductor layers LP11 and LP12 are layers implementing the 11^{th} and 12^{th} inductors L11 and L12 shown in FIG. 3, respectively, and may be disposed on the second conductive pattern layer TL2, as shown in FIGS. 7A and 7B.

The second inductor layer may be disposed across the second conductive pattern layer TL2 and the third conductive pattern layer TL3. That is, the second inductor layer includes a second upper inductor layer, which has one end connected to the first capacitor layers CP11 and CP12 and is disposed on the second conductive pattern layer TL2, as shown in FIG. 7B, and a second lower inductor layer, which has one end connected to the other end of the second upper inductor layer and the other end connected to the second capacitor layer CP2 and is disposed on the third conductive pattern layer TL3, as shown in FIG. 8B. In this case, the second upper inductor layer includes a 21^{st} upper inductor layer LP2U1 and a 22^{nd} upper inductor layer LP2U2, and the second lower inductor layer includes a 21^{st} lower inductor layer LP2L1 and a 22^{nd} lower inductor layer LP2L2.

The 21^{st} upper inductor layer LP2U1 and the 21^{st} lower inductor layer LP2L1 implement the 21^{st} inductor L21 shown in FIG. 3, and the 22^{nd} upper inductor layer LP2U2 and the 22^{nd} lower inductor layer LP2L2 implement the 22^{nd} inductor L22 shown in FIG. 3.

In addition, the third inductor layers LP31 and LP32 are layers implementing the 31^{st} and 32^{nd} inductors L31 and L32 shown in FIG. 3, respectively, and may be disposed on the first conductive pattern layer TL1, as shown in FIGS. 5A and 6.

In addition, the fourth inductor layers LP41 and LP42 are layers implementing the 41^{st} and 42^{nd} inductors L41 and L42 shown in FIG. 3, respectively, and may be disposed on the third conductive pattern layer TL3, as shown in FIGS. 8A and 8B.

According to the embodiment, each of the first, second, third, and fourth inductor layers may have a planar shape bent at least once in a horizontal direction. For example, as shown in FIGS. 7B and 8B, the second upper inductor layers LP2U1 and LP2U2, the second lower inductor layers LP2L1 and LP2L2, and the fourth inductor layers LP41 and LP42 may have a planar shape bent once in the horizontal direction, and as shown in FIG. 6, the third inductor layers LP31 and LP32 may have a planar shape bent twice in the horizontal direction.

Meanwhile, the capacitance pattern layers may include first capacitor layers CP11 and CP12, a second capacitor layer CP2, third capacitor layers CP31 and CP32, and a fourth capacitor layer CP4.

As shown in FIGS. 7A and 7B, the first capacitor layers having a first capacitance may include 11^{th} and 12^{th} capacitor layers CP11 and CP12, which are disposed on the second conductive pattern layer TL2 and face each other while being spaced apart from each other by a first distance X1 in the first direction, which is the horizontal direction.

As shown in FIGS. 8A and 8B, the second capacitor layer CP2 having a second capacitance may be disposed on the third conductive pattern layer TL3.

As shown in FIGS. 9A and 9B, the third capacitor layers having a third capacitance may include 31^{st} and 32^{nd} capacitor layers CP31 and CP32, which are disposed on the fourth conductive pattern layer TL4 and face each other while being spaced apart from each other by a second distance X2 in the first direction, which is the horizontal direction.

According to the embodiment, if each of the first and second distances X1 and X2 is less than 50 μm, undesired parasitic capacitance may be generated, which reduces the bandwidth of a passband or causes spurious signals that may affect harmonics, and if each of the first and second distances X1 and X2 is greater than 300 μm, a change in performance is insignificant, and the size of the multilayer filter increases. Therefore, each of the first and second distances X1 and X2 may be 50 μm to 300 μm, but the embodiments are not limited thereto.

As shown in FIGS. 10A and 10B, the fourth capacitor layer CP4 having a fourth capacitance may be disposed on the fifth conductive pattern layer TL5.

Referring to FIGS. 5A, 6A, 7A, 8A, 9A, and 10A, the first capacitor layers CP11 and CP12 and the third capacitor layers CP31 and CP32 may be connected to each other, and the second capacitor layer CP2 and the fourth capacitor layer CP4 may be electrically connected to each other. That is, the 11^{th} capacitor layer CP11 may be electrically connected to the 31^{st} capacitor layer CP31, and the 12^{th} capacitor layer CP12 may be electrically connected to the 32^{nd} capacitor layer CP32.

To this end, the multilayer filter may include first and second vias. The first via connects the first capacitor layers CP11 and CP12 to the third capacitor layers CP31 and CP32, and the second via VA2 connects the second capacitor layer CP2 to the fourth capacitor layer CP4.

The first via may include an 11^{th} via VA11 and a 12^{th} via VA12.

The 11^{th} via VA11 electrically connects the 11^{th} capacitor layer CP11 to the 31^{st} capacitor layer CP31, and the 12^{th} via VA12 electrically connects the 12^{th} capacitor layer CP12 to the 32^{nd} capacitor layer CP32.

The 11^{th} and 12^{th} vias VA11 and VA12 pass through the second capacitor layer CP2, and the second capacitor layer CP2 may include first and second through-holes TH1 and TH2, as shown in FIG. 8B. The 11^{th} via VA11 may pass through the first through-hole TH1, and the 12^{th} via VA12 may pass through the second through-hole TH2. In order to allow the 11^{th} and 12^{th} vias VA11 and VA12 to be electrically isolated from the second capacitor CP2, the diameter of the first through-hole TH1 may be formed to be greater than the diameter of the 11^{th} via VA11, and the diameter of the second through-hole TH2 may be formed to be greater than the diameter of the 12^{th} via VA12.

Referring to FIG. 9B, the 31^{st} and 32^{nd} capacitor pattern layers CP31 and CP32 may have a planar shape and may be disposed to be spaced apart from each other with the second via VA2 interposed therebetween. Accordingly, the 31^{st} and 32^{nd} capacitor pattern layers CP31 and CP32 may be electrically isolated from the second via VA2.

The inductance pattern layers and the capacitance pattern layers described above may be connected to each other in the vertical and horizontal directions by the vias in order to implement the circuit shown in FIG. 3.

The multilayer filter according to the embodiment may include the 31^{st}, 32^{nd}, 41^{st}, 42^{nd}, 5^{th}, 61^{st}, 62^{nd}, 71^{st}, and 72^{nd} vias VA31, VA32, VA41, VA42, VA5, VA61, VA62, VA71, and VA72.

The 31^{st} via VA31 is connected to the 11^{th} capacitor layer CP11, one end of the 21^{st} upper inductor layer LP2U1, and one end of the 11^{th} inductor layer LP11, and is not connected to the first and second ground layers GL1 and GL2.

The 32^{nd} via VA32 is connected to the 12^{th} capacitor layer CP12, one end of the 22^{nd} upper inductor layer LP2U2, and one end of the 12^{th} inductor layer LP12, and is not connected to the first and second ground layers GL1 and GL2.

The 41^{st} via VA41 is connected to the other end of the 11^{th} inductor layer LP11 and the first port P1, and the 42^{nd} via VA42 is connected to the other end of the 12^{th} inductor layer LP12 and the second port P2.

The 41^{st} and 42^{nd} vias VA41 and VA42 are not connected to the first and second ground layers GL1 and GL2.

The fifth via VA5 connects one end of the 31^{st} inductor layer LP31 and one end of the 32^{nd} inductor layer LP32 to the first ground layer GL1. The other end of the 31^{st} inductor layer LP31 may be connected to the 11^{th} via VA11, and the other end of the 32^{nd} inductor layer LP32 may be connected to the 12^{th} via VA12.

The 61^{st} via VA61 is connected to the other end of the 21^{st} upper inductor layer LP201 and one end of the 21^{st} lower inductor layer LP2L1, and the 62^{nd} via VA62 is connected to the other end of the 22^{nd} upper inductor layer LP2U2 and one end of the 22^{nd} lower inductor layer LP2L2. In this case, the 61^{st} and 62^{nd} vias VA61 and VA62 are not connected to the first and second ground layers GL1 and GL2.

In this case, the other end of the 21^{st} lower inductor layer LP2L1 is connected to the second capacitor layer CP2, and the other end of the 22^{nd} lower inductor layer LP2L2 is also connected to the second capacitor layer CP2.

The 71^{st} via VA71 is connected to one end of the 41^{st} inductor layer LP41 and the second ground layer GL2, and the 72^{nd} via VA71 is connected to one end of the 42^{nd} inductor layer LP42 and the second ground layer GL2.

The other end of each of the 41^{st} inductor layer LP41 and the 42^{nd} inductor layer LP42 is connected to the second capacitor layer CP2.

In addition, the multilayer filter according to the embodiment may further include an eighth via. The eighth via serves to connect the first ground layer GL1 to the second ground layer GL2. As shown, the eighth via may include ten eighth vias VA81 to VA810, but the embodiments are not limited to any specific number of eighth vias.

In addition, the multilayer filter according to the embodiment may further include ninth vias VA91 and VA92, as shown in FIGS. 5B, 7B, 8B, and 9B. The ninth vias VA91 and VA92 serve to connect the second to fourth conductive pattern layers TL2, TL3, and TL4 to each other. As shown in FIGS. 5A, 7A, 8A, and 9A, the ninth vias VA91 and VA92 may be omitted.

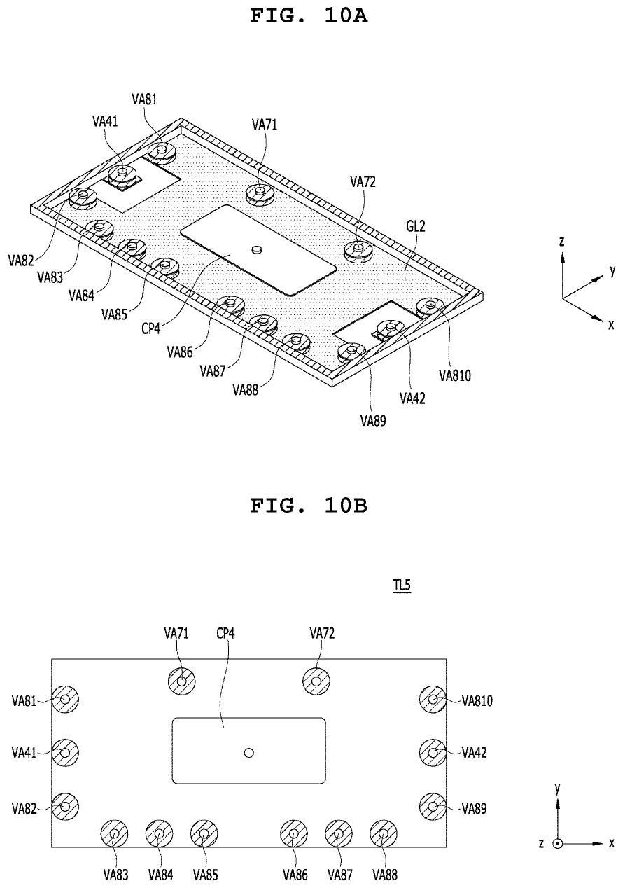

FIG. 11 is a cross-sectional view of the multilayer filter shown in FIG. 4, taken along line I-I′, in which only the first and second ground layers GL1 and GL2 and the first to third capacitor layers CP11, CP12, CP2, and CP3 are shown.

The first capacitance of each of the 11^{th} and 12^{th} capacitors C11 and C12 may include 11^{th}, 12^{th}, and 13^{th} capacitances.

The 11^{th} capacitance is formed by the first capacitor layers CP11 and CP12 and the second capacitor layer CP2 facing each other, the 12^{th} capacitance is formed by the second capacitor layer CP2 and the third capacitor layers CP31 and CP32 facing each other, and the 13^{th} capacitance is formed by the third capacitor layers CP31 and CP32 and the fourth capacitor layer CP4 facing each other.

In detail, the above-described capacitance pattern layers may implement the capacitors C11, C12, C21, C22, and C3 shown in FIG. 3 as follows.

First, the capacitance of the 11^{th} capacitor C11 shown in FIG. 3 is a result of combination of an 11^{th} capacitance formed by the 11^{th} capacitor layer CP11 and the second capacitor layer CP2 facing each other with a distance Z111 therebetween, a 12^{th} capacitance formed by the second capacitor layer CP2 and the 31^{st} capacitor layer CP31 facing each other with a distance Z112 therebetween, and a 13^{th} capacitance formed by the 31^{st} capacitor layer CP31 and the fourth capacitor layer CP4 facing each other with a distance Z113 therebetween.

Similarly, the capacitance of the 12^{th} capacitor C12 is a result of combination of an 11^{th} capacitance formed by the 12^{th} capacitor layer CP12 and the second capacitor layer CP2 facing each other with a distance Z121 therebetween, a 12^{th} capacitance formed by the second capacitor layer CP2 and the 32^{nd} capacitor layer CP32 facing each other with a distance Z122 therebetween, and a 13^{th} capacitance formed by the 32^{nd} capacitor layer CP32 and the fourth capacitor layer CP4 facing each other with a distance Z123 therebetween.

Unlike the first capacitance C1 described above, the second and third capacitances may correspond to parasitic capacitances.

First, the capacitance of the 21^{st} capacitor C21 is a result of combination of a parasitic capacitance caused between the 11^{th} capacitor layer CP11 and the first ground layer GL1 spaced a distance Z211 from each other, a parasitic capacitance caused between the 11^{th} capacitor layer CP11 and the second ground layer GL2 spaced a distance Z212 from each other, a parasitic capacitance caused between the 31^{st} Capacitor layer CP31 and the first ground layer GL1 spaced a distance Z213 from each other, and a parasitic capacitance caused between the 31^{st} capacitor layer CP31 and the second ground layer GL2 spaced a distance Z214 from each other.

The capacitance of the 22^{nd} capacitor C22 is a result of combination of a parasitic capacitance caused between the 12^{th} capacitor layer CP12 and the first ground layer GL1 spaced a distance Z221 from each other, a parasitic capacitance caused between the 12^{th} capacitor layer CP12 and the second ground layer GL2 spaced a distance Z222 from each other, a parasitic capacitance caused between the 32^{nd} capacitor layer CP32 and the first ground layer GL1 spaced a distance Z223 from each other, and a parasitic capacitance caused between the 32^{nd} capacitor layer CP32 and the second ground layer GL2 spaced a distance Z224 from each other.

The capacitance of the third capacitor C3 is a result of combination of a parasitic capacitance between the second capacitor layer CP2 and the first ground layer GL1 spaced a distance Z31 from each other, a parasitic capacitance between the second capacitor layer CP2 and the second ground layer GL2 spaced a distance Z32 from each other, a parasitic capacitance between the fourth capacitor layer CP4 and the first ground layer GL1 spaced a distance Z33 from each other, and a parasitic capacitance between the fourth capacitor layer CP4 and the second ground layer GL2 spaced a distance Z34 from each other.

In order to obtain a desired capacitance, the ground layers GL1 and GL2 and the capacitor layers CP11, CP12, CP2, CP31, CP32, and CP4, which are adjacent to each other in the vertical direction, may overlap each other in the vertical direction to a desired extent, the dielectric constant of the dielectric layers disposed between the ground layers GL1 and GL2 and the capacitor layers CP11, CP12, CP2, CP31, CP32, and CP4 may be adjusted, or an area in which the capacitor layers forming the capacitance face each other may be adjusted.

A multilayer filter according to another embodiment may include only the first to third conductive pattern layers TL1 to TL3 and the first to fourth dielectric layers DL1 to DL4 (i.e., N=3) described above. That is, according to another embodiment, the fourth and fifth conductive pattern layers TL4 and TL5 and the first and second vias VA11, VA12, and VA2 may be omitted from FIGS. 4 to 11. With this exception, the multilayer filter according to another embodiment is identical to the multilayer filter according to the above embodiment, and thus redundant descriptions thereof will be omitted.

In addition, after the second upper inductor layer is placed on the second conductive pattern layer TL2 and the second lower inductor layer is placed on the third conductive pattern layer TL3, the second upper inductor layer and the second lower inductor layer are connected using 51^{st} and 52^{nd} vias VA51 and VA52, so that the second inductors L21 and L22 increase in length so as to obtain a desired inductance.

In the multilayer filter according to the above embodiment, because the 11^{th} and 12^{th} capacitor layers CP11 and CP12 are connected to the 31^{st} and 32^{nd} capacitor layers CP31 and CP32 by the 11^{th} and 12^{th} vias VA11 and VA12, a structure in which the capacitors are connected in parallel may be achieved, thereby increasing the first capacitance to a desired extent.

However, when there is no need to increase the first capacitance, as in another embodiment, the fourth and fifth conductive pattern layers TL4 and TL5 and the 11^{th}, 12^{th}, and second vias VA11, VA12, and VA2 may be omitted.

Hereinafter, the operation of the multilayer filter shown in FIG. 3 according to the embodiment will be described with reference to the accompanying drawings.

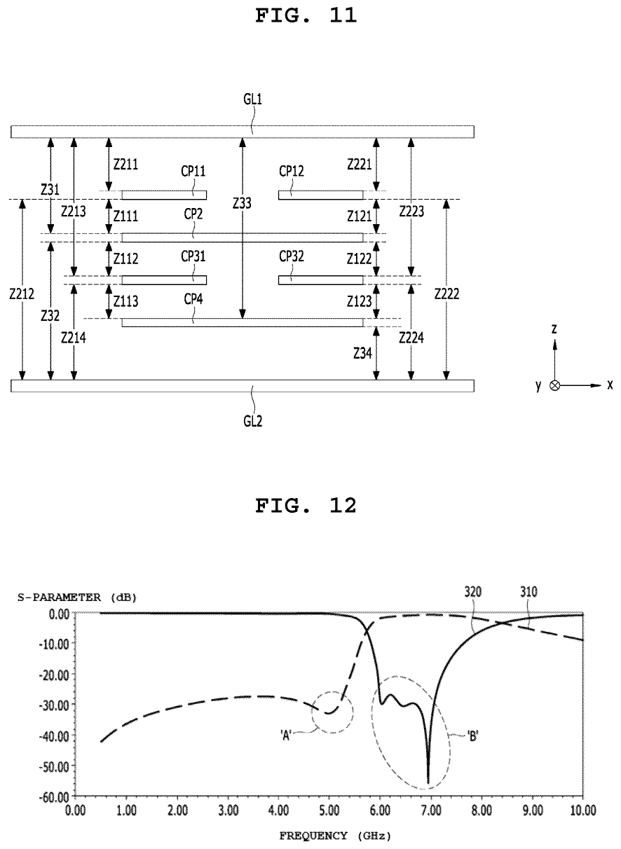

FIG. 12 is a graph showing a result of examining the performance of the multilayer filter according to the embodiment, in which the horizontal axis represents frequency, and the vertical axis represents S-parameter.

FIG. 12 shows a simulation result in which the multilayer filter according to the embodiment is applied to Wi-Fi 6E having a passband of 5.925 GHz to 7.125 GHz, and the insertion loss is −5 dB or less.

The 21^{st} and 22^{nd} inductors L21 and L22 and the 11^{th} and 12^{th} capacitors C11 and C12 shown in FIG. 3 serve to create a transmission zero. Referring to FIG. 12, two transmission zeros may be generated in portion A of the transmission zero 310. In FIG. 12, the transmission zeros overlap and are therefore shown as a single zero.

In addition, the 31^{st} and 32^{nd} inductors L31 and L32, the 41^{st} and 42^{nd} inductors L41 and L42, the 21^{st} capacitor C21, the 22^{nd} capacitor C22, and the third capacitor C3 shown in FIG. 3 serve to form a resonator. Referring to FIG. 12, it can be seen that the multilayer filter has the characteristics of a third-order resonator 320 having three resonance points, as indicated by portion B.

Hereinafter, a front end module according to an embodiment will be described with reference to the accompanying drawings.

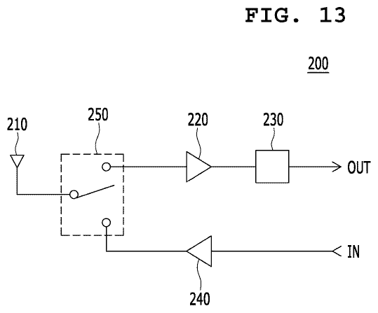

FIG. 13 is a block diagram of a front end module 200 according to an embodiment.

The front end module 200 according to the embodiment shown in FIG. 13 may include an antenna 210, first and second amplifiers 220 and 240, a multilayer filter 230, and a switch 250.

The first amplifier 220 may amplify a signal received through the antenna 210, and may provide a result of amplification to the multilayer filter 230. For example, the first amplifier 220 may be a low-noise amplifier (LNA).

The multilayer filter 230 may filter the signal amplified by the first amplifier 220, and may output the filtered signal through an output terminal OUT. The multilayer filter may correspond to the multilayer filters 100 and 100A according to the above-described embodiments, and thus redundant descriptions thereof will be omitted.

The second amplifier 240 may amplify a signal input through an input terminal IN, and may transmit a result of amplification through the antenna 210. For example, the second amplifier 240 may be a power amplifier (PA).

The switch 250 may be disposed between the antenna and each of an input of the first amplifier 220 and an output of the second amplifier 240 to select signal paths therebetween.

According to the embodiment, when the multilayer filter 100 or 100A is embedded in the front end module using Inductance & Capacitance in Package (LCiP) technology and when the second capacitors C21 and C22 and the third capacitor C3, which are shunt capacitors, are implemented as parasitic capacitances between the 11^{th}, 12^{th}, 2^{nd}, 31^{st}, 32^{nd}, and 4^{th} capacitor layers CP11, CP12, CP2, CP31, CP32, and CP4 and the first and second ground layers GL1 and GL2 as described above, it is unnecessary to form separate capacitor layers for the second capacitors C21 and C22 and the third capacitor C3.

That is, in the case of the multilayer filter according to the embodiment, in order to obtain the capacitances of the 11^{th} and 12^{th} capacitors C11 and C12, the 11^{th}, 12^{th}, 2^{nd}, 31^{st}, 32^{nd}, and 4^{th} capacitor layers CP11, CP12, CP2, CP31, CP32, and CP4 are disposed, and the capacitances of the 21^{st}, 22^{nd}, and 3^{rd} capacitors C21, C22, and C3 are formed using the parasitic capacitances between the 11^{th}, 12^{th}, 2^{nd}, 31^{st}, 32^{nd}, and 4^{th} capacitor layers CP11, CP12, CP2, CP31, CP32, and CP4 and the first and second ground layers GL1 and GL2. Accordingly, the parasitic capacitors may be used without requiring separate capacitor layers for forming the capacitances of the 21^{st}, 22^{nd}, and 3^{rd} capacitors C21, C22, and C3. As a result, the size of the multilayer filter 100 or 100A or the front end module 200 may be reduced, and the frequency may be tuned with ease.

In addition, the capacitance (e.g., the first capacitance) may be easily increased within a limited size by vertically stacking the capacitor layers and interconnecting the same.

In addition, the inductance (e.g., the inductance of the second inductor) may be easily increased by vertically stacking the inductor layers to increase the length thereof.

The multilayer filter and the front end module according to the above-described embodiments may be applied to fields employing a frequency band of 6 GHz or higher, such as antenna modules for televisions, mobile devices, Bluetooth, and Wi-Fi.

While the present disclosure has been particularly shown and described with reference to exemplary embodiments thereof, these embodiments are only proposed for illustrative purposes, and do not restrict the present disclosure, and it will be apparent to those skilled in the art that various changes in form and detail may be made without departing from the essential characteristics of the embodiments set forth herein. For example, respective configurations set forth in the embodiments may be modified and applied. Further, differences in such modifications and applications should be construed as falling within the scope of the present disclosure as defined by the appended claims.

### MODE FOR DISCLOSURE

Various embodiments have been described in the best mode for carrying out the disclosure.

### INDUSTRIAL APPLICABILITY

The multilayer filter and the front end module including the same according to the embodiments may be used in mobile communication terminals and the like.

1.-10. (canceled)

11. A multilayer filter, comprising:
first and second ground layers;
a plurality of conductive pattern layers disposed between the first ground layer and the second ground layer; and
a dielectric layer disposed between the first and second ground layers and the plurality of conductive pattern layers,
wherein adjacent conductive pattern layers among the plurality of conductive pattern layers include capacitance pattern layers forming a first capacitance,
wherein at least some of the plurality of conductive pattern layers include inductance pattern layers forming an inductor, and
wherein the capacitance pattern layers face the first and second ground layers to form a parasitic capacitance, and the multilayer filter a signal having a desired frequency band using the first capacitance, the inductor, and the parasitic capacitance.

12. The multilayer filter according to claim 11, wherein the capacitance pattern layers and the inductance pattern layers have a symmetrical shape with respect to an imaginary horizontal line passing through a center of a long axis of the multilayer filter and parallel to a short-axis direction of the multilayer filter.

13. The multilayer filter according to claim 11, wherein the plurality of conductive pattern layers includes first to third conductive pattern layers sequentially stacked between the first ground layer and the second ground layer.

14. The multilayer filter according to claim 13, wherein the inductance pattern layers include:
a first inductor layer disposed on the second conductive pattern layer;
a second inductor layer disposed across the second conductive pattern layer and the third conductive pattern layer;
a third inductor layer disposed on the first conductive pattern layer; and
a fourth inductor layer disposed on the third conductive pattern layer.

15. The multilayer filter according to claim 14, wherein each of the first, second, third, and fourth inductor layers has a planar shape bent at least once in a horizontal direction.

16. The multilayer filter according to claim 14, wherein the capacitance pattern layers include:
a first capacitor layer disposed on the second conductive pattern layer; and
a second capacitor layer disposed on the third conductive pattern layer and facing the first capacitor layer to form the first capacitance.

17. The multilayer filter according to claim 16, wherein the plurality of conductive pattern layers further includes fourth and fifth conductive pattern layers sequentially stacked between the third conductive pattern layer and the second ground layer.

18. The multilayer filter according to claim 17, wherein the capacitance pattern layers further include:
a third capacitor layer connected to the first capacitor layer; and
a fourth capacitor layer connected to the second capacitor layer.

19. The multilayer filter according to claim 18, comprising:
a first via connecting the first capacitor layer to the third capacitor layer; and
a second via connecting the second capacitor layer to the fourth capacitor layer.

20. The multilayer filter according to claim 18, wherein the first capacitance includes:
an 11^{th} capacitance formed by the first capacitor layer and the second capacitor layer facing each other;
a 12^{th} capacitance formed by the second capacitor layer and the third capacitor layer facing each other; and
a 13^{th} capacitance formed by the third capacitor layer and the fourth capacitor layer facing each other.

21. The multilayer filter according to claim 18, wherein the parasitic capacitance includes:
a first parasitic capacitance formed by the first and third capacitor layers and the first and second ground layers facing each other; and
a second parasitic capacitance formed by the second and fourth capacitor layers and the first and second ground layers facing each other.

22. The multilayer filter according to claim 18, wherein the first capacitor layer includes 11^{th} and 12^{th} capacitor layers facing each other while being spaced apart from each other by a first distance in a horizontal direction, and
wherein the third capacitor layer includes 31^{st} and 32^{nd} capacitor layers facing each other while being spaced apart from each other by a second distance in the horizontal direction.

23. The multilayer filter according to claim 22, wherein the first via includes:
an 11^{th} via connecting the 11^{th} capacitor layer to the 31^{st} capacitor layer; and
a 12^{th} via connecting the 12^{th} capacitor layer to the 32^{nd} capacitor layer.

24. The multilayer filter according to claim 23, wherein the second capacitor layer includes:
a first through-hole formed to allow the 11^{th} via to pass therethrough and spaced apart from the 11^{th} via; and
a second through-hole formed to allow the 12^{th} via to pass therethrough and spaced apart from the 12^{th} via.

25. The multilayer filter according to claim 23, wherein the second inductor layer includes:
a second upper inductor layer having one end connected to the first capacitor layer and disposed on the second conductive pattern layer; and
a second lower inductor layer having one end connected to the other end of the second upper inductor layer and the other end connected to the second capacitor layer and disposed on the third conductive pattern layer.

26. The multilayer filter according to claim 25, further comprising:
a 31^{st} via connected to the 11^{th} capacitor layer, to one end of a 21^{st} upper inductor layer, which is a part of the second upper inductor layer, and to one end of an 11^{th} inductor layer, which is a part of the first inductor layer;
a 32^{nd} via connected to the 12^{th} capacitor layer, to one end of a 22^{nd} upper inductor layer, which is another part of the second upper inductor layer, and to one end a 12^{th} inductor layer, which is another part of the first inductor layer;
a 41^{st} via connected to the other end of the 11^{th} inductor layer and to a first port;
a 42^{nd} via connected to the other end of the 12^{th} inductor layer and to a second port;
a fifth via connecting one end of a 31^{st} inductor layer, which is a part of the third inductor layer, to the first ground layer;
a 61^{st} via connected to the other end of the 21^{st} upper inductor layer;
a 62^{nd} via connected to the other end of the 22^{nd} upper inductor layer;
a 71^{st} via connected to one end of a 41^{st} inductor layer, which is a part of the fourth inductor layer;
a 72^{nd} via connected to one end of a 42^{nd} inductor layer, which is another part of the fourth inductor layer; and
at least one eighth via connecting the first ground layer to the second ground layer.

27. The multilayer filter according to claim 26, wherein the other end of the 31^{st} inductor layer is connected to the 11^{th} via,
wherein one end and the other end of a 32^{nd} inductor layer, which is another part of the third inductor layer, are connected to the 5^{th} via and the 12^{th} via, respectively,
wherein a 21^{st} lower inductor layer, which is a part of the second lower inductor layer, has one end and the other end connected to the 61^{st} via and the second capacitor layer, respectively,
wherein a 22^{nd} lower inductor layer, which is another part of the second lower inductor layer, has one end and the other end connected to the 62^{nd} via and the second capacitor layer, respectively, and
wherein the other end of each of the 41^{st} inductor layer and the 42^{nd} inductor layer is connected to the second capacitor layer.

28. A multilayer filter, comprising:
an 11^{th} inductor having one end connected to a first port;
a 12^{th} inductor having one end connected to a second port;
a 21^{st} inductor having one end connected to the other end of the 11^{th} inductor;
a 22^{nd} inductor having one end connected to the other end of the 12^{th} inductor;
a 31^{st} inductor connected between the other end of the 11^{th} inductor and ground;
a 32^{nd} inductor connected between the other end of the 12^{th} inductor and the ground;
a 41^{st} inductor connected between the other end of the 21^{st} inductor and the ground;
a 42^{nd} inductor connected between the other end of the 22^{nd} inductor and the ground;
an 11^{th} capacitor connected in parallel to the 21^{st} inductor;
a 12^{th} capacitor connected in parallel to the 22^{nd} inductor;
a 21^{st} capacitor connected in parallel to the 31^{st} inductor;
a 22^{nd} capacitor connected in parallel to the 32^{nd} inductor; and
a third capacitor connected in parallel to the 41^{st} and 42^{nd} inductors between a connection point of the 21^{st} inductor and the 22^{nd} inductor and the ground.

29. The multilayer filter according to claim 28, wherein the 21^{st}, 22^{nd}, and third capacitors are parasitic capacitances.

30. A front end module, comprising:
an antenna;
a first amplifier configured to amplify a signal received through the antenna;
the multilayer filter according to claim 11, the multilayer filter being configured to filter the signal amplified by the first amplifier and to output the filtered signal;
a second amplifier configured to amplify a signal to be transmitted through the antenna; and
a switch disposed between the antenna and each of an input of the first amplifier and an output of the second amplifier.
